(19) United States
(12) Patent Application Publication
(10) Pub. No.: US 2016/0190028 A1
(43) Pub. Date: Jun. 30, 2016

(54) METHOD AND STRUCTURE FOR FAN-OUT WAFER LEVEL PACKAGING

(71) Applicant: NANTONG FUJITSU MICROELECTRONICS CO., LTD., NANTONG (CN)

(72) Inventor: Lei Shi, Nantong (CN)

(73) Assignee: NANTONG FUJITSU MICROELECTRONICS CO., LTD.

(21) Appl. No.: 14/975,895

(22) Filed: Dec. 21, 2015

(30) Foreign Application Priority Data
Dec. 24, 2014 (CN) 2014-10818051.5

(51) Int. Cl. H01L 23/31; H01L 23/00; H01L 23/528; H01L 21/56; H01L 23/29; H01L 21/66; H01L 21/683; H01L 21/768

(52) U.S. Cl. CPC H01L 23/3128; H01L 21/6835; H01L 24/11; H01L 21/76877; H01L 21/56; H01L 23/296; H01L 22/26; H01L 24/83; H01L 24/49; H01L 24/14; H01L 23/528; H01L 2221/68359; H01L 2924/0105; H01L 2924/01047; H01L 2924/01028; H01L 2924/01046; H01L 2924/01079; H01L 2924/186; H01L 2924/07025; H01L 2924/0665; H01L 2924/066; H01L 2924/069; H01L 2924/0635; H01L 2924/01029; H01L 2924/05442; H01L 2924/0675; H01L 2924/06; H01L 2224/83121; H01L 2224/48227

(57) ABSTRACT

A method for fan-out wafer level packaging includes: providing a carrier substrate; forming a strippable protective film with a polarity of openings; forming at least one metal layer in the openings; removing the carrier substrate; mounting a plurality of chips onto the metal layer and electrically connecting the chips to the metal layer; packing the chips, the metal layer, and the strippable protective film by using a packaging layer; forming a plurality of redistribution layers; and finally, forming soldering balls on the surfaces of the redistribution layers.

### CROSS-REFERENCES TO RELATED APPLICATIONS

This application claims the priority of Chinese Patent Application No. CN201410818051.5, filed on Dec. 24, 2014, the entire content of which is incorporated herein by reference.

### FIELD OF THE DISCLOSURE

The present disclosure generally relates to the field of semiconductor packaging technology and, more particularly, relates to a method and a structure for highly-integrated fan-out wafer level packaging.

### BACKGROUND

In current semiconductor industry, electronic packaging has become an important aspect of the development of the industry. Decades of development of packaging technology has come to a stage where demands on packaging high-density and small-sized electronics become the mainstream direction of the packaging technology. Fan-out wafer level packaging (FOWLP) is an embedded type packaging method during wafer level processing and is also a major advanced packaging technology for packaging a large quantity of inputs and outputs (I/O) with high integration flexibility.

In addition, the FOWLP technology can realize multiple-chip integration along vertical and horizontal directions in a single package without using a substrate. Therefore, the FOWLP technology is now being developed into a next-generation packaging technology, such as multiple-chip packaging, low profile packaging, 3D system-in package, etc. As electronic products are developed to be thinner and lighter with a higher pin density and a lower cost, single-chip packaging technology has gradually become unable to meet the industry needs. The emergence of a new packaging technology, i.e., wafer level packaging technology, provides an opportunity to develop low-cost packaging for the packaging industry.

Currently, wafer level fan-out packaging structure uses a method of wafer reconstruction and wafer level redistribution to realize packaging of fan-out structure of chips, and the wafer level fan-out packaging structure is then cut to eventually form individual single packages. However, according to the present disclosure, several aspects of the existing methods still need to be further improved. First, because the strength of the packaging material used to encapsulate the chip structures may be relatively low, the packaging material may provide insufficient support for the fan-out structure and, thus, the packaging material may not be applicable to thin structure packaging. Second, the fan-out structure in current packaging technology is relatively specialized and application of the fan-out structure is not wide enough. Third, the existing methods are not conducive to reduce product cost. Finally, the density of the I/O terminals is relatively small.

For example, Chinese Patent No. CN201210243958.4 discloses a fan-out wafer level chip packaging method. The structure to be packaged includes chips, metal microstructures, high-density wiring layers, a silicon body, bonding layers, and soldering ball bumps. The metal microstructures are formed on the chips through a process including sputtering, photolithography, and electroplating. The packaging method includes: mounting the chips on the high-density wiring layers with the active side of the chips facing to the high-density wiring layers; forming concave silicon cavities by etching the silicon body using a photomask; placing the silicon body onto the high-density wiring layers with the chips disposed in the concave silicon cavities; bonding the high-density wiring layers to the silicon body through the bonding layers; heating and curing a packaging layer and the bonding layers to complete the packaging process. However, the disclosed method is complex, high cost, not suitable for thin structure packaging.

For another example, Chinese Patent No. CN201110032264.1 discloses a highly-integrated fan-out wafer level packaged structure. The units to be packaged include chips and passive devices. The units to be packaged have a functional surface. A packaging layer is formed on a surface opposite to the functional surface. The packaging layer encapsulates the units to be packaged after curing. Trenches are formed on the surface of the packaging layer corresponding to positions between the units to be packaged. Chinese Patent No. CN201110032591.7 discloses the corresponding highly-integrated fan-out wafer level packaging method. The method includes: forming an adhesive layer on a carrier substrate; attaching the units to be packaged including the chips and the passive devices to the adhesive layer with the functional surface of the units to be packaged; forming the packaging layer on the surface of the carrier substrate with the chips and the passive devices attached on and then heating and curing the packaging layer to encapsulate the units to be packaged; forming trenches on the surface of the packaging layer at the positions between the units to be packaged; finally, removing the carrier substrate and the adhesive layer. The structure and method in the above patents may avoid warpage of the packaging layer during subsequent processes after the wafer was packaged, thus may improve the quality of the packaged products.

For another example, Chinese Patent No. CN201110069815.1 discloses a fan-out system level packaging method. The method includes: providing a carrier substrate; forming a strippable film on the carrier substrate; forming a protective layer on the strippable film; forming redistribution metal layers in the protective layer; forming wire packaging layers on the protective layer with the wire packaging layers electrically connected to the redistribution metal layers; forming wire-bonding packaging layers on the top of the wire packaging layers with all the packaging layers electrically connected with each other; removing the carrier substrate and the strippable film to expose the surfaces of the redistribution layers formed in the protective layer; forming metal soldering balls on the exposed surfaces of the redistribution layers. The method in the above patent may reduce the internal resistance and inductance of the system and suppress interference between chips.

Although the above existing technology has, to some degree, improved the packaging method, some problems in current fan-out wafer level packaging technology such as complex process and high cost are still not resolved. Therefore, the existing technology may not be suitable for thin structure packaging.

The disclosed method and structure for fan-out wafer level packaging in the present disclosure are directed to solve one or more problems set forth above and other problems in the art.

### BRIEF SUMMARY OF THE DISCLOSURE

One aspect of the present disclosure includes a method for fan-out wafer level packaging. The fan-out wafer level packaging method includes: providing a carrier substrate; forming a strippable protective film with a polarity of openings; forming at least one metal layer in the openings; removing the carrier substrate; mounting a plurality of chips onto the metal layer and electrically connecting the chips to the metal layer; packing the chips, the metal layer, and the strippable protective film by using a packaging layer; forming a plurality of redistribution layers; and finally, forming soldering balls on the surfaces of the redistribution layers.

Another aspect of the present disclosure provides a fan-out wafer level packaged structure. The fan-out wafer level packaged structure includes a plurality of chips with electrodes, a strippable protective film having a plurality of openings, a metal layer having multiple portions, a plurality of wire leads, a plurality of protective dielectric layers, a plurality of redistribution layers, a plurality of soldering balls, and a packaging layer. The metal layer is formed in the openings of the strippable protective film. The chips are individually mounted on the metal layer and the electrodes of the chips are electrically connected to the metal layer. The packaging layer encapsulates the chips, the wire leads, and top surfaces of the metal layer and the strippable protective film. The redistribution layers are electrically connected to multiple portions of the metal layer. The protective dielectric layers fill the spaces between the redistribution layers. Each soldering ball is formed on an exposed surface of the corresponding redistribution layer.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic view of a carrier substrate consistent with disclosed embodiments;

FIG. 2 illustrates a schematic view of a structure with a protective layer formed on the carrier substrate according to disclosed embodiments;

FIG. 3 illustrates a schematic view of a structure with a plurality of openings formed in the protective layer according to disclosed embodiments;

FIG. 4 illustrates a schematic view of a structure with a discrete first metal layer formed in the opening according to disclosed embodiments;

FIG. 5 illustrates a schematic view of a structure with a discrete second metal layer formed on the first metal layer according disclosed embodiments;

FIG. 6 illustrates a schematic diagram for removing the carrier substrate according to disclosed embodiments;

FIG. 7 illustrates a schematic view of a structure with a chip mounted on the surface of the first metal layer according to disclosed embodiments;

FIG. 8 illustrates a schematic view of a packaged structure according to disclosed embodiments;

FIG. 9 illustrates a schematic view of a structure with a protective dielectric layer with openings formed on the packaged structure consistent to disclosed embodiments;

FIG. 10 illustrates a schematic view of a structure with a plurality of redistribution layers formed in the protective dielectric layer according to disclosed embodiments;

FIG. 11 illustrates a schematic view of a structure after a ball-planting process according to disclosed embodiments;

FIG. 12 illustrates a schematic view of a CCD imaging alignment device and a metallic needle according to disclosed embodiments;

FIG. 13 illustrates a schematic view of chip claws according to disclosed embodiments; and

FIG. 14 illustrates a flowchart of an exemplary packaging method consistent with disclosed embodiments.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts. In the drawings, only a portion of the semiconductor structures is shown to schematically illustrate the structures at certain stages of the disclosed packaging process.

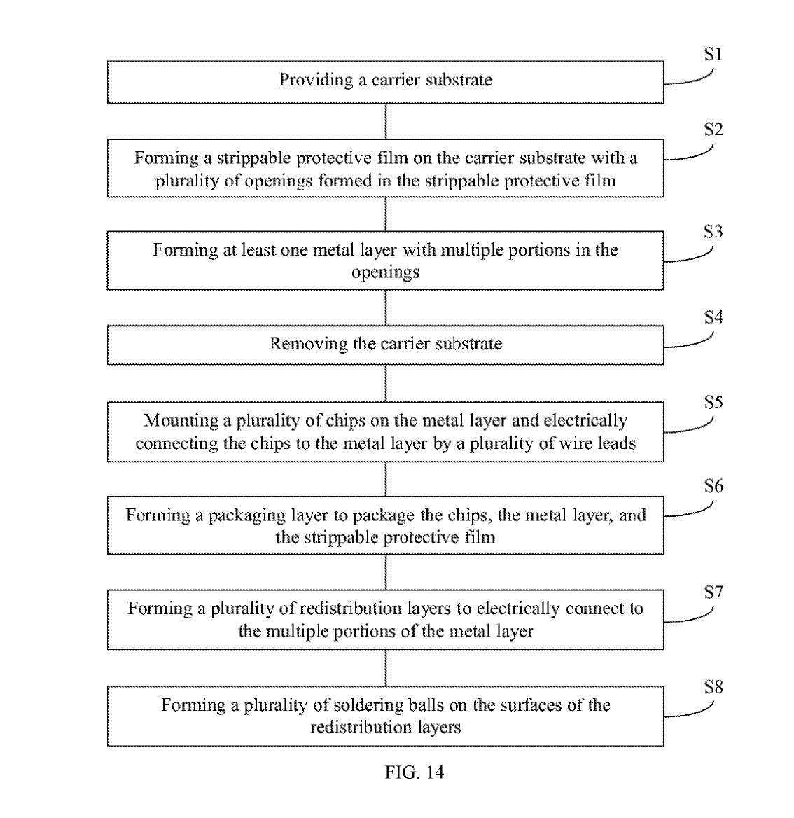

The present disclosure provides a fan-out wafer level packaging method to solve one or more problems set forth above and other problems in the existing methods. FIG. 14 shows a flowchart of an exemplary fan-out wafer level packaging method consistent with disclosed embodiments.

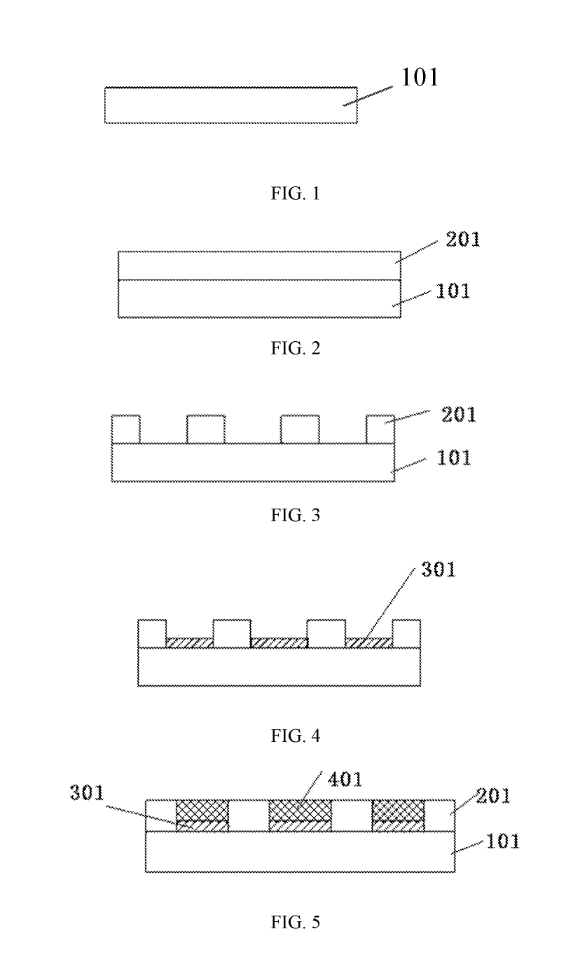

Referring to FIG. 14, at the beginning of the packaging process, a carrier substrate is provided (S1). FIG. 1 shows a schematic view of the carrier substrate 101. The carrier substrate 101 provides a platform for integrating circuits.

The carrier substrate 101 may be made of glass, alumina, single-crystalline silicon, aluminum nitride, beryllium oxide, silicon carbide, or sapphire. The carrier substrate 101 may have relatively strong strength and flatness to reduce the failure rate of the packaged devices and also avoid warpage during the packaging process. The principle to select carrier substrate is that the selected carrier substrate may be easily peeled off in a subsequent process, have desired corrosion resistance, and have no changes in the physical or chemical properties when placed in contact with an adhesive layer and, thus, can be reused.

Returning to FIG. 14, a strippable protective film having a plurality of openings may be formed on the carrier substrate (S2). FIG. 2 shows a schematic view of the corresponding structure.

Referring to FIG. 2, a strippable protective film 201 may be coated on a front side of the carrier substrate 101. The strippable protective film 201 may be one of ultraviolet (UV) film, polyethylene terephthalate (PET) film, polyethylene (PE) film, orientated polypropylene (OPP) film, and polyvinyl alcohol film, etc. In one embodiment, the strippable protective film 201 is a UV film.

UV film has strippable adhesive properties and, thus, can be easily peeled off from the carrier substrate. In addition, UV film can be used at a temperature of 130˜150° C. and has a relatively low shrinking rate, desired flexibility, and ideal adhesive continuity. Therefore, by selecting UV film as the strippable protective film 201, the strippable protective film 201 may be continuous and flexible with a relatively low expansion or shrinking rate and, thus, warpage of the structure to be packaged may be avoided. Further, a relatively high upper working temperature of the strippable protective film 201 may be conducive to a subsequent curing process of a packaging layer. In addition, because the strippable protective film 201 may be easily peeled off from a subsequently packaged structure, warpage and damage of the packaged structure may be further reduced.

The UV film may be formed by screen printing. The thickness of the printed UV film may be in a range of 10-20 μm. After printing, a plurality of patterned openings or trenches may be formed in certain areas of the UV film. FIG. 3 shows a schematic view of the corresponding structure. Referring to FIG. 3, the openings may be formed as hollow trenches.

The plurality of patterned openings may be formed in certain areas of the UV film by using a photolithography method. Specifically, a pattern of a mask plate may be transferred onto the UV film under irradiation of a UV light; curing reaction may take place in areas of the UV film irradiated by the UV light; uncured areas of the UV film may then be washed away to form the openings in certain areas of the UV film.

In certain other embodiments where the strippable protective film 201 is a PET film, a PE film, an OPP film, or a polyvinyl alcohol film, forming a plurality of openings in certain areas of the strippable protective film 201 may require a more complex process. Specifically, first, the surface of the strippable protective film 201 may require a plasma treatment, a fluoride coating treatment, or a silicone oil coating treatment to make the surface of the strippable protective film 201 have significantly small amount but steady adhesiveness. Then, the plurality of openings may be formed in certain areas of the strippable protective film 201 by a plasma dry etching method.

Returning to FIG. 14, further, at least one metal layer may be formed in the patterned openings (S3). FIG. 4 shows a schematic cross-section view of a structure with a first metal layer 301 formed in the openings. The first metal layer 301 may be formed discretely in the plurality of openings in the strippable protective film 201, i.e., the first metal layer 301 may include multiple portions (connected or unconnected) formed in the openings. Optionally, a second metal layer may be formed on the first metal layer 301 to form a double-layer structure. FIG. 5 shows a schematic view of a structure with a second metal layer 401 formed on the top of the first metal layer 301. The first metal layer 301 may be made of Sn or Ag. The second metal layer 401 may be made of Cu, Ni, Pd, or Au. The first metal layer 301 and the second metal layer 401 may be formed by one of electroplating, electroless plating, vacuum evaporation, and chemical vapor deposition process.

The first metal layer 301 may also be formed by a sputtering or an electroless plating method. Specifically, a sputtering method may include following steps: a suitable amount of argon gas is filled into a high-vacuum coating chamber; an DC voltage of several hundred kilovolts is applied on a cathode (a cylindrical or a planar target) and an anode (sidewall of the coating chamber) to produce magnetically-controlled abnormal glow discharge in the coating chamber; the diluted argon gas is then ionized; argon ions are accelerated by the electric field near the cathode and bombard the surface of the target at the cathode so that the surface atoms at the target may sputter out and then be deposited onto a surface of a substrate to form a film layer. Using the sputtering method, the adhesion between the deposited layer and the substrate may be strong and the deposited layer may be dense and uniform.

The second metal layer 401 may be formed by an electroplating method. In semiconductor chip packaging process, the line-width may be in micron or submicron (0.15-0.09 μm), and such line-width may cause more restrict requirements for subsequent processes such as ball-planting, etc. Therefore, the metal coating may be required to have sufficient strength against stripping. Because of the existing first metal layer 301, when further forming the second metal layer 401, the electroplating method may be straightforward and the finished second metal layer 401 may have tight and uniform bonding with the first metal layer 301, meeting the strength requirements.

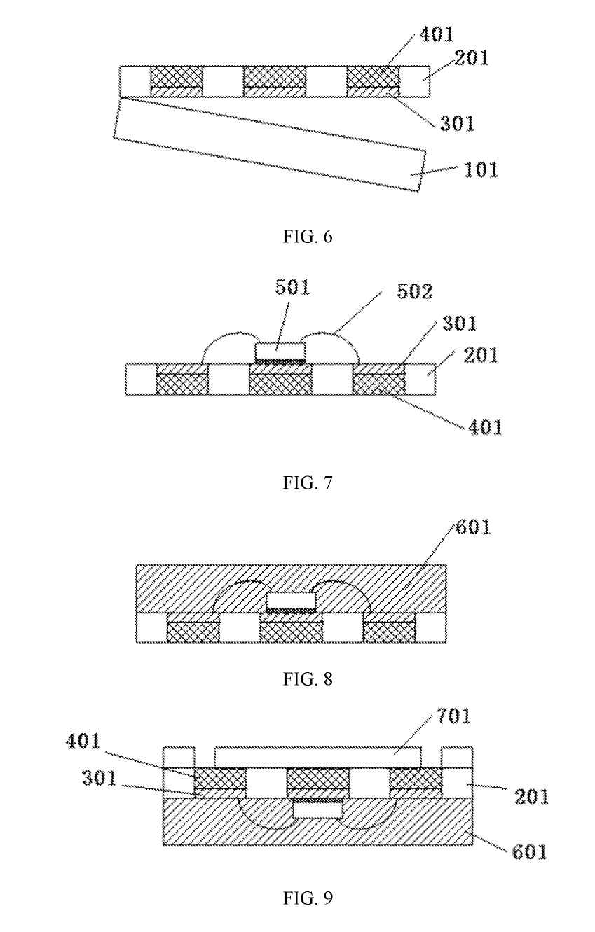

Returning to FIG. 14, further, the carrier substrate may be removed (S4). FIG. 6 shows a schematic diagram for removing the carrier substrate 101. Referring to FIG. 6, because of the strippable protective film 201, the carrier substrate 101 may be easily peeled off. The reason to remove the carrier substrate 101 is to conveniently perform subsequent chip mounting and wiring or ball-planting processes. In disclosed embodiments, removing the carrier substrate 101 before wiring or ball-planting may reduce the cost and may also make the packaged products thinner and, thus, may be conducive to the densification trend of the development.

Further, returning to FIG. 14, a plurality of semiconductor chips may be mounted on the metal layers and electrical connections to the chips may also be made by wiring or ball-planting (S5). FIG. 7 shows a schematic view of a corresponding structure after electrical connections are arranged.

Referring to FIG. 7, after removing the carrier substrate, the protective layers and the metal layers form a frame structure. The frame structure may be flipped to have the exposed surface of the first metal layer facing up. A chip 501 is then mounted on the exposed surface of the first metal layer 301. The active side of the chip 501 may face to the metal layer 301 or may face to a direction opposite to the first metal layer 301. In one embodiment, the active side of the chip 501 faces to a direction away from the metal layer 301. The method to mount the chip 501 on the first metal layer 301 may be one of hot pressing bonding, solder bonding, ultrasonic bonding, adhesive bonding, etc.

Further, electrical connections between the first metal layer 301 and the chip 501 may be arranged by wire or solder-planting bonding. Specifically, wiring or ball-planting bonding mainly has three forms: hot pressing bonding, ultrasonic bonding, and gold-wire ball bonding. In one embodiment, referring to FIG. 7, a plurality of wire leads 502 are bounded to the electrodes (not shown) on the chips 501 and the first metal layer 301. The bonding method may be an ultrasonic bonding method or a gold-wire ball bonding.

During the chip mounting process, deflection of chips is a very difficult technical problem. A large deflection distance may result in a lower yield. How to promptly eliminate deflection of chips is always a technical challenge. According to the present disclosure, an excess of soldering flux during the chip mounting process may be an important aspect to cause deflection of the chips. In one embodiment, referring to FIG. 12, a CCD image alignment device 1001 is installed in the system to detect deflection of chips during a mounting process. In addition, a metallic needle 1002 may be installed to absorb an excess amount of soldering flux.

Further, referring to FIG. 13, chip claws 1003 may also be installed to correct positions of chips. The chip claws 1003 have fingers moving along four directions. Working in coordination with the CCD image alignment device 1001, the chip claws 1003 microscopically adjust positions of chips based on the monitoring results so that precise positions of chips may be ensured.

Further, returning to FIG. 14, the chips, the metal layers, and the strippable protective film may be packaged or encapsulated (S6). FIG. 8 shows a schematic view of the corresponding structure after packaging.

Referring to FIG. 8, the chips, the metal layers, and the strippable protective film are packaged by a packaging layer 601. The material used to form the packaging layer 601 may be one of silicone resin, polyimide, phenol resin, epoxy resin, polyurethane, and acrylic resin. In one embodiment, an appropriate amount of alumina powder or fumed silica may be added into the packaging material to further improve the property of the material. The property-improved packaging material may have high adhesive strength, desired electrical properties, ideal chemical corrosion resistance, a wide working temperature range, a low shrinking rate, ideal sealing performance, and flexibility in reshaping. In addition, during a curing process of the property-improved packaging material, volatile materials may unlikely be produced while pores, cracks, and peeling phenomenon may also unlikely emerge.

Specifically, the packaging process may include: first, attaching the chips on the frame structure by using an organic conductive adhesive; then, connecting aluminum soldering bumps on the chips to pins on the frame structure using gold wire or aluminum wire through wire bonding; packaging the chips and the frame structure using packaging material through an injection mold process. Finally, in a subsequent process, a layer of lead-tin alloy may be coated on the surface of the outer leads and then be punched out from a strip structure and shaped to a desired form.

Further, returning to FIG. 14, a plurality of redistribution layers may be formed (S7). The formation of the redistribution layers may include: forming a protective dielectric layer on the top of the second metal layer with the protective dielectric layer covering a portion of the second metal layer; forming at least one redistribution layer on the portion of the second metal layer not covered by the dielectric layer.

In one embodiment, referring to FIG. 9, a protective dielectric layer 701 is formed on the exposed surface of the second metal layer 401 and the surface of the strippable protective film 201. The protective dielectric layer 701 covers only a portion of the surface of the second metal layer 401 that is electrically connected to aluminum soldering bumps on the chips. A plurality of openings are formed in the protective dielectric layer 701 to ensure that the corresponding second metal layer 401 is not completely covered by the protective dielectric layer 701.

The protective dielectric layer 701 may be made of one of photosensitive ink, thermosetting ink, coating, SiO₂ film, UV adhesive, PET film, polyester film, PP film, PE film, etc. The protective dielectric layer 701 may be formed by a method including coating, screen printing, vapor deposition, etc. When the protective dielectric layer 701 is an UV adhesive, a photolithography method may be used to form the openings. When the protective dielectric layer 701 is made any other material, a plasma dry etching process may be used to selectively etch a portion of the protective dielectric layer 701 to form the openings.

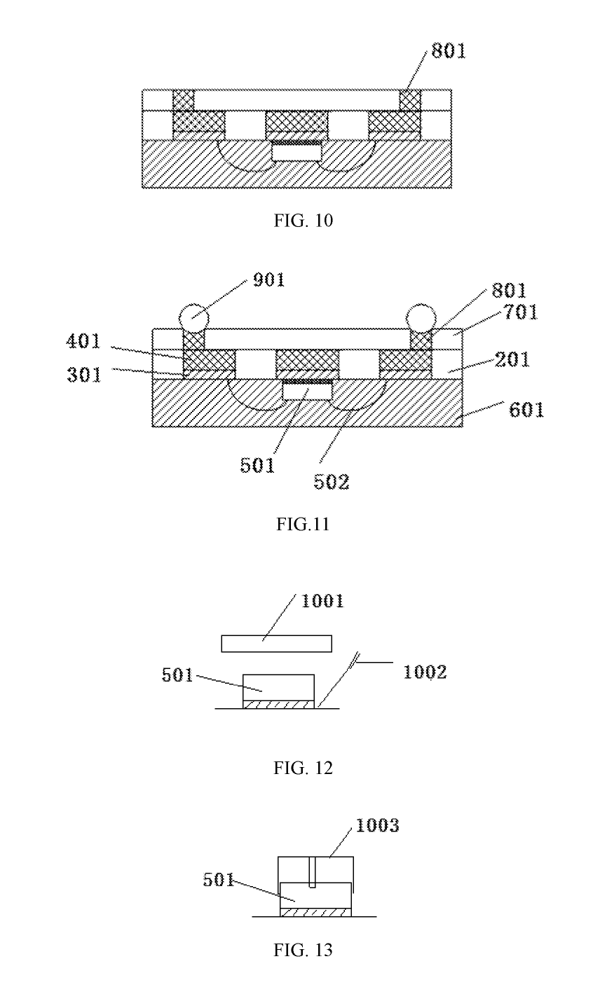

Further, referring to FIG. 10, a plurality of discrete redistribution layers 801 may be formed to fill up the openings in the protective dielectric layer 701. The redistribution layers 801 may have a single-layer or a multiple-layer structure. The redistribution layers 801 may be made of one of Cu, Ag, Sn, Ni, Pd, and Au, or one of their alloys. The formation of the redistribution layers is to increase the thickness of the second metal layer, thus may conducive to a subsequent ball-planting process and improve the product yield. The redistribution layers may be formed by an electroless plating process. That is, a coating layer may be formed on the surface of the substrate without having a current passing through. Therefore, the electroless plating method is simple, energy-saving, and environmentally friendly, the service life of the method may be longer than other methods, and the coating may be uniformly.

In certain other embodiments, the redistribution layers and the protective dielectric layers may have multiple levels. Therefore, the above process to form a single level of protective dielectric layers and redistribution layers may be repeated to complete the multiple-layer structure. The redistribution layers are electrically connected with each other through all the layers and form conductive connections for the corresponding second metal layer. In addition, redistribution layers of different levels may form tilted conductive connections. That is, the conductive connections may not vertically point to the corresponding portion of the first or the second metal layer and, thus, the redistribution layers at the final level may distributed more uniformly. With the redistribution layers spread more uniformly on the surface of the packaged structure, ball-planting in a subsequent process may be easy.

Further, returning to FIG. 14, soldering balls may be disposed on the surfaces of the redistribution layers (S8). FIG. 11 shows a schematic view of the corresponding structure with a plurality of soldering balls 901 formed on the redistribution layers 801.

Referring to FIG. 11, a plurality of micro-sized soldering balls 901 are placed on the surface of the redistribution layers 801. After performing a back-flow and curing process, the soldering balls 901 may be tightly linked with the corresponding redistribution layers 801 and, thus, an array of soldering ball bumps may be formed. Soldering ball-planting is a reliable, simple, and efficient technique, and using such a technique, the product cost may be significantly reduced.

Alternatively, after the formation of the protective dielectric layers and the redistribution layers, an insulating layer may be coated on the surfaces of the redistribution layers. In addition, a plurality of openings may be formed in the insulating layer to define electrodes for subsequent processes such as testing.

The disclosed method for fan-out wafer level packaging has the advantages of simple process, low cost, and environmental protection. In addition, the disclosed method is applicable to packaging structures with a high density of I/O terminals and particularly suitable for thin structure packaging.

The present disclosure also provided a fan-out wafer level packaged structure. As shown in FIG. 11, the fan-out wafer level packaged structure includes a plurality of chips with electrodes, a strippable protective film having a plurality of openings, a metal layer having multiple portions, a plurality of wire leads, a plurality of protective dielectric layers, a plurality of redistribution layers, a plurality of soldering balls, and a packaging layer. The metal layer is formed in the openings of the strippable protective film. The chips are individually mounted on the metal layer and the electrodes of the chips are electrically connected to the metal layer. The packaging layer encapsulates the chips, the wire leads, and top surfaces of the metal layer and the strippable protective film. The redistribution layers are electrically connected to multiple portions of the metal layer. The protective dielectric layers fill the spaces between the redistribution layers. Each soldering ball is formed on an exposed surface of the corresponding redistribution layer.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fan-out wafer level chip packaging, comprising:
providing a carrier substrate;
forming a strippable protective film with a plurality of openings on a surface of the carrier substrate;
forming at least one metal layer having multiple portions in the plurality of openings;
removing the carrier substrate;
mounting a plurality of chips on the metal layer and electrically connecting the chips to the metal layer;
packaging the chips and the metal layer;
forming a plurality of redistribution layers on surfaces of the metal layer to electrically connect to the metal layer; and
forming soldering balls on surfaces of the redistribution layers.

2. The fan-out wafer level packaging method according to claim 1, wherein:
the metal layer has a double-level structure including a first metal layer and a second metal layer;
the first metal layer is made of one of Sn, Ag, Ni, Pd, and Au;
the second metal layer is made of one of Sn, Ag, Ni, Pd, and Au;
the first metal layer is formed on a surface of the carrier substrate; and
the second metal layer is formed on the first metal layer.

3. The fan-out wafer level chip packaging method according to claim 2, wherein the first metal layer and the second metal layer are made of different materials.

4. The fan-out wafer level packaging method according to claim 1, wherein forming the plurality of redistribution layers on surface of the metal layer further includes:
forming a plurality of protective dielectric layers on a surface of the packaged structure opposite to the packaging layer to cover a portion of the metal layer; and
forming the plurality of redistribution layers on another portion of the metal layer uncovered by the protective dielectric layer;

5. The fan-out wafer level chip packaging method according to claim 4, wherein the redistribution layers have a single-level or a multiple-level structure.

6. The fan-out wafer level chip packaging method according to claim 5, wherein forming the multiple-level structure of the redistribution layers further including:
forming a plurality of protective dielectric layers on the surface of the packaged structure opposite to the packaging layer with each protective dielectric layer covering a portion of the surface area corresponding to the metal layer;
forming a plurality of redistribution layers on an uncovered portion of the surface area by the protective dielectric layers; and
repeating the above processes until all levels of redistribution layers are formed, wherein:
the multiple levels of redistribution layers are tightly linked with each other to form conductive connections for the multiple portions of the metal layer.

7. The fan-out wafer level chip packaging method according to claim 1, wherein the carrier substrate is made of one of glass, alumina, single-crystalline silicon, aluminum nitride, beryllium oxide, silicon carbide, and sapphire.

8. The fan-out wafer level chip packaging method according to claim 1, wherein the strippable protective film is one of ultraviolet film, polyethylene terephthalate film, polyethylene film, orientated polypropylene OPP film, and polyvinyl alcohol film.

9. The fan-out wafer level chip packaging method according to claim 1, wherein the packaging material is one of silicone resin, polyimide, phenol resin, epoxy resin, polyurethane, and acrylic resin.

10. The fan-out wafer level chip packaging method according to claim 1, wherein the protective dielectric layers are made of one of Cu, Ag, Sn, Ni, Pd, Au, and their alloys.

11. The fan-out wafer level chip packaging method according to claim 1, wherein the redistribution layers are made of one of photosensitive ink, thermosetting ink, coating, SiO2 film, ultraviolet adhesive, polyethylene terephthalate film, polyester film, polypropylene film, and polyethylene film.

12. The fan-out wafer level chip packaging method according to claim 1, wherein mounting the chips on the metal layer further includes:
using a CCD image alignment device to monitor deflection of the chips;
using chip claws to correct the positions of the chips; and
using a metallic needle to absorb an excess amount of soldering flux.

13. The fan-out wafer level chip packaging method according to claim 12, wherein the chip claws have fingers moving along four directions to correct positions of chips based on monitoring results of the CCD image alignment device.

14. A fan-out wafer level packaged structure, comprising:
a plurality of chips having electrodes on the chips;
a strippable protective film having a plurality of openings;
a metal layer having a plurality of portions;
a plurality of wire leads;
a plurality of protective dielectric layers;
a plurality of redistribution layers;
a plurality of soldering balls; and
a packaging layer, wherein:
the metal layer is formed in the openings of the strippable protective film;
the chips are individually mounted on the metal layer;
the wire leads connect the electrodes of the chips to the metal layer;
the packaging layer encapsulates the chips, the wire leads, and a top surface of the metal layer and the strippable protective film;
the redistribution layers are electrically connected to the multiple portions of the metal layer;
the protective dielectric layers fill the spaces between the redistribution layers; and
each soldering ball is formed on an exposed surface of the corresponding redistribution layer.

15. The fan-out wafer level packaged structure according to 14, wherein:
each metal layer has a double-level structure including a first metal layer and a second metal layer;
the first metal layer is in contact with the packaging layer; and
the second metal layer is in contact with a redistribution layer.

16. The fan-out wafer level packaged structure according to 14, wherein:
the redistribution layers have a single-level or a multiple-level structure.
